(19) United States
(12) Patent Application Publication
(10) Pub. No.: US 2026/0136921 A1
(43) Pub. Date: May 14, 2026

(54) HIGH DENSITY METAL FINGER CAPACITOR WITH FRONTSIDE AND BACKSIDE LAYER COMBINATION

(71) Applicant: QUALCOMM Incorporated, San Diego, CA (US)

(72) Inventors: John Jianhong ZHU, San Diego, CA (US); Junjing BAO, San Diego, CA (US); Abhishek JAIN, San Diego, CA (US); Giridhar NALLAPATI, San Diego, CA (US)

(21) Appl. No.: 18/946,332

(22) Filed: Nov. 13, 2024

(51) Int. Cl. H01L 23/522; H10D 1/68; H10D 84/00

(52) U.S. Cl. CPC H10W 20/496; H10D 1/714; H10D 1/716; H10D 84/101

(57) ABSTRACT

A chip includes a combined capacitor. The combined capacitor includes a frontside capacitor, a backside capacitor, and vertical coupling structures coupling the frontside capacitor and the backside capacitor in parallel.

### BACKGROUND

### Field

Aspects of the present disclosure relate generally to capacitors, and, more particularly, to capacitors integrated on a chip.

### Background

Capacitors may be integrated on a chip (i.e., die) for various applications. For example, integrated capacitors may be used to build a capacitor array in an analog-to-digital converter (ADC) and/or a digital-to-analog converter (DAC).

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip including a combined capacitor. The combined capacitor includes a frontside capacitor, a backside capacitor, and vertical coupling structures coupling the frontside capacitor and the backside capacitor in parallel.

A second aspect relates to a chip. The chip includes a backside capacitor and a shield. The backside capacitor includes a first terminal extending in a first direction, first fingers coupled to the first terminal and extending in a second direction orthogonal to the first direction, a second terminal extending in the first direction, and second fingers coupled to the second terminal and extending in the second direction, wherein the first fingers and the second fingers are interlaced. The shield includes gates extending over the first fingers and the second fingers in the first direction.

A third aspect relates to a chip. The chip includes unit capacitors coupled in parallel. Each of the unit capacitors includes a respective frontside capacitor, a respective backside capacitor, and respective vertical coupling structures coupling the respective frontside capacitor and the respective backside capacitor in parallel.

### BRIEF DESCRIPTION OF THE DRAWINGS

FIG. 1A shows a side view of an example of a chip including frontside metal layers, an

active device, and vias according to certain aspects of the present disclosure.

FIG. 1B shows a perspective view of the active device implemented with a gate-all-around transistor according to certain aspects of the present disclosure.

FIG. 1C shows the perspective view of FIG. 1B with a gate of the active device shown in phantom according to certain aspects of the present disclosure.

FIG. 1D shows a side view of the chip further including backside metal layers according to certain aspects of the present disclosure.

FIG. 2A shows a top view of an example of capacitors integrated on the chip according to certain aspects of the present disclosure.

FIG. 2B shows an example of capacitors arrayed in two directions to form a two-dimensional (2D) array according to certain aspects of the present disclosure.

FIG. 2C shows another example of capacitors arrayed in two directions to form a 2D array according to certain aspects of the present disclosure.

FIG. 3 shows a top view of another example of capacitors integrated on the chip according to certain aspects of the present disclosure.

FIG. 4 shows an example of a capacitor including a frontside capacitor and a backside capacitor according to certain aspects of the present disclosure.

FIG. 5A shows a side view of an example of a vertical coupling structure coupling a first terminal of the frontside capacitor of FIG. 4 and a first terminal of the backside capacitor of FIG. 4 according to certain aspects of the present disclosure.

FIG. 5B shows a side view of an example of a vertical coupling structure coupling a second terminal of the frontside capacitor of FIG. 4 and a second terminal of the backside capacitor of FIG. 4 according to certain aspects of the present disclosure.

FIG. 6 shows an example of a capacitor including multiple instances of the capacitor of FIG. 4 according to certain aspects of the present disclosure.

FIG. 7 shows another example of a capacitor including a frontside capacitor and a backside capacitor according to certain aspects of the present disclosure.

FIG. 8A shows a side view of an example of a vertical coupling structure coupling a first terminal of the frontside capacitor of FIG. 7 and a first terminal of the backside capacitor of FIG. 7 according to certain aspects of the present disclosure.

FIG. 8B shows a side view of an example of a vertical coupling structure coupling a second terminal of the frontside capacitor of FIG. 7 and a second terminal of the backside capacitor of FIG. 7 according to certain aspects of the present disclosure.

FIG. 9A shows an example of a capacitor including multiple instances of the capacitor of FIG. 7 according to certain aspects of the present disclosure.

FIG. 9B shows another example of a capacitor including multiple instances of the capacitor of FIG. 7 according to certain aspects of the present disclosure.

FIG. 10A shows an example of a shield for shielding one or more backside capacitors according to certain aspects of the present disclosure.

FIG. 10B shows an example in which the shield includes gates and vias that are coupled together according to certain aspects of the present disclosure.

FIG. 11 shows an example of a capacitor array according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

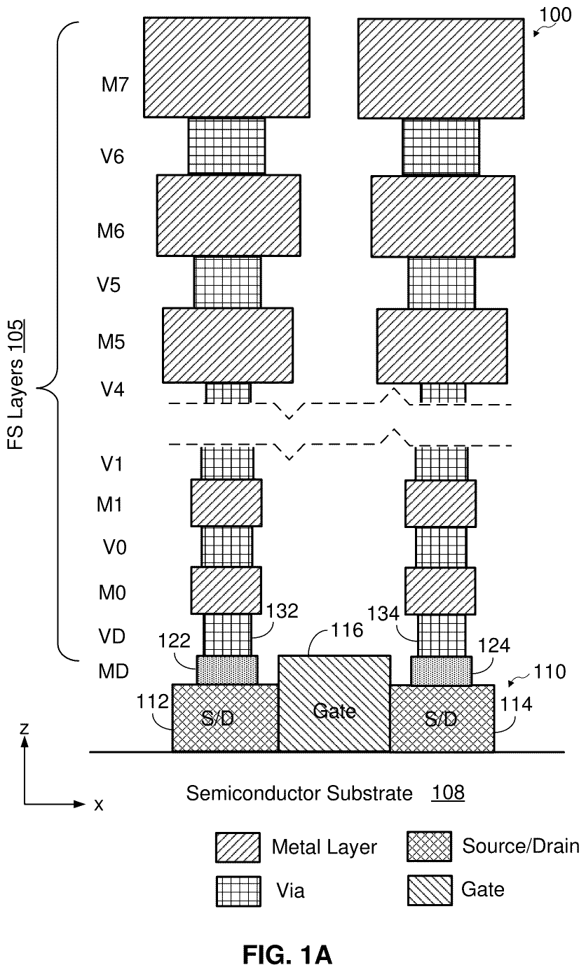

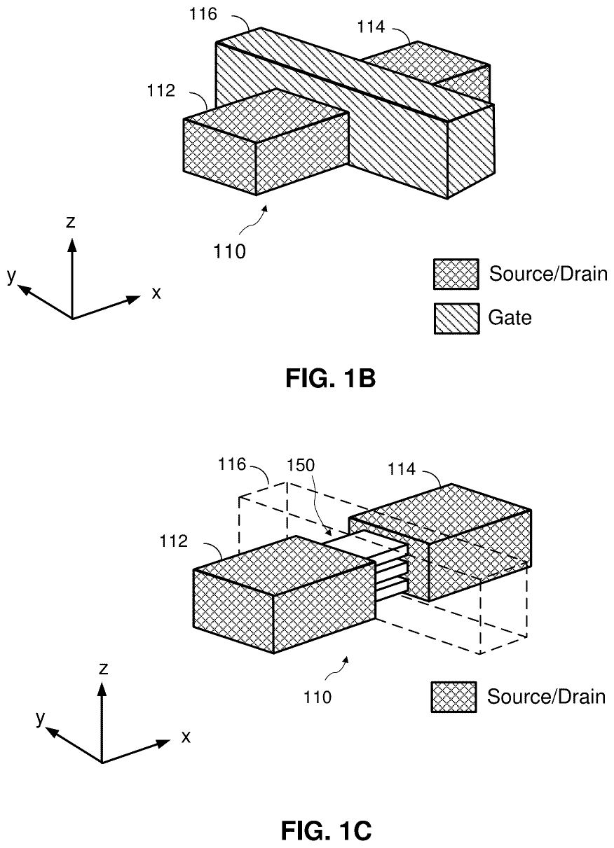

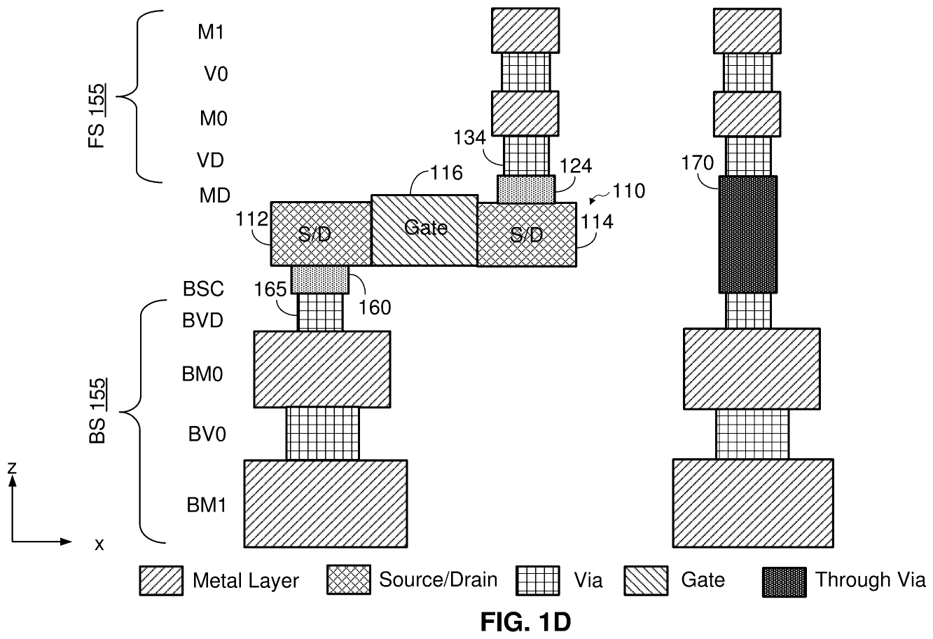

FIG. 1A shows a side view of an example of a chip 100 (i.e., die) according to certain aspects. The chip 100 may include many devices integrated on the chip 100 including active devices (e.g., transistors) and capacitors. In this regard, FIG. 1A shows an example of an active device 110 integrated on the chip 100. Although one active device 110 is shown in FIG. 1A for simplicity, it is to be appreciated that the chip 100 may include many active devices. As discussed further below, the active device 110 may be implemented with a gate-all-around transistor, a fin field-effect transistor (FinFET), or another type of transistor.

The chip 100 also includes frontside layers 105 formed over the active device 110. As discussed further below, the frontside layers 105 may be used to provide signal routing and/or frontside power distribution for the active device 110 and other active devices integrated on the chip 100.

In the example shown in FIG. 1A, the active device 110 includes a first source/drain 112, a second source/drain 114, and a gate 116 disposed between the first source/drain 112 and the second source/drain 114. As used herein, the term “source/drain” means a source, a drain, or both. In example shown in FIG. 1A, the chip 100 includes a first contact 122 disposed on the first source/drain 112 and a second contact 124 disposed on the second source/drain 114. The contacts 122 and 124 provide source/drain contacts for the active device 110 and may be formed from a contact metal layer MD.

The gate 116 may include a gate metal (e.g., a high-k metal gate (HKMG)), polysilicon, and/or another gate material. The active device 110 may also include one or more channels 150 (shown in FIG. 1C) coupled between the first source/drain 112 and the second source/drain 114 and passing through the gate 116. As used herein, a “channel” is a structure that conducts current between a source and a drain of an active device.

FIG. 1B shows a perspective view of the active device 110 for an example in which the active device 110 is implemented with a gate-all-around transistor according to certain aspects. FIG. 1C shows the perspective view of FIG. 1B in which the gate 116 of the active device 110 is shown in phantom in order to show the one or more channels 150 passing through the gate 116. In this example, the one or more channels 150 are stacked vertically and are spaced apart from one another in the z direction. Each of the one or more channels 150 may include a nanosheet, a nanowire, or the like. In this example, each of the first source/drain 112 and the second source/drain 114 may include an epitaxial layer (e.g., layer of epitaxially grown or deposited silicon).

It is to be appreciated that the active device 110 is not limited to the gate-all-around transistor. For example, in other implementations, the active device 110 may be implemented with a FinFET. In this example, each of the one or more channels 150 may include a fin that is orientated in the vertical direction.

Although one gate 116 is shown in FIGS. 1A to 1C, it is to be appreciated that the active device 110 may include multiple gates arranged in parallel and coupled to one another (e.g., through metal layer M0 or another metal layer).

Returning to FIG. 1A, the frontside layers 105 include metal layers (also referred to as a metal stack). The metal layers may be patterned (e.g., using lithography and etching) to provide signal routing and/or frontside power distribution. In the example shown in FIG. 1A, the bottom-most metal layer among the frontside layers 105 is referred to as metal layer M0. The metal layer immediately above metal layer M0 is referred to as metal layer M1, the metal layer immediately above metal layer M1 is referred to as metal layer M2, the metal layer immediately above metal layer M2 is referred to as metal layer M3, and so forth. In the example shown in FIG. 1A, the metal layers go up to metal layer M7. Note that metal layers M2 to M4 are not shown in FIG. 1A for ease of illustration. It is to be appreciated that the frontside layers 105 are not limited to the number of metal layers shown in the example in FIG. 1A and that the frontside layer 105 may include a smaller number of metal layers or a larger number of metal layers in other examples.

It is to be appreciated that the present disclosure is not limited to the nomenclature in which the bottom-most metal layer is referred to as metal layer M0. For instance, in another example, the bottom-most metal layer may be referred to as metal layer M1 instead of metal layer M0. Also, it is to be appreciated that one or more of the metal layers may be designated with a letter other than M in other examples. Accordingly, it is to be appreciated that the metal layers are not limited to the exemplary designations used in FIG. 1A.

In certain aspects, the upper metal layers have larger thicknesses than the lower metal layers. For example, in the example shown in FIG. 1A, metal layer M7 has a much larger thickness than the bottom-most metal layer M0 (which provides routing to individual active devices). It is to be appreciated that the metal layers M0 to M7 are not necessarily drawn to scale in FIG. 1A and that the relative thicknesses of the metal layers may differ from the example shown in FIG. 1A.

The frontside layers 105 also includes vias that provide coupling between the metal layers. The vias include vias V0 to V6. In this example, the vias V0 provide coupling between metal layer M0 and metal layer M1, the vias V1 provide coupling between metal layer M1 and metal layer M2, the vias V2 provide coupling between metal layer M2 and metal layer M3, and so forth.

The chip 100 may also include a via 132 disposed between the contact 122 and metal layer M0 for coupling the first source/drain 112 to metal layer M0. The chip 100 also includes a via 134 disposed between the contact 124 and metal layer M0 for coupling the second source/drain 114 to metal layer M0. For example, the via 132 may couple the first source/drain 112 to a supply rail in metal layer M0 and the vias 134 may couple the second source/drain 114 to signal routing in metal layer M0, or vice versa. The chip 100 may also include a via (not shown) coupling the gate 116 to metal layer M0 (e.g., signal routing in metal layer M0).

In certain aspects, the chip 100 includes backside layers to facilitate backside routing. In these aspects, most or all of the semiconductor substrate 108 is removed to form backside layers under the active devices (e.g., the active device 110) on the chip 100. For example, after formation of the active devices and the frontside layers 105, a carrier wafer (not shown) may be bonded to the top of the chip 100 for structural support. The chip 100 may then be flipped to expose the backside of the semiconductor substrate 108, and most or all of the semiconductor substrate 108 may be grounded and/or polished off (e.g., using chemical mechanical polishing (CMP)). Backside layers may then be formed under the active devices on the chip 100.

In this regard, FIG. 1D shows an example of backside layers 155 formed under the active device 110. In this example, the backside layers 155 include backside metal layers, which may be patterned (e.g., using lithography and etching) to form a backside power distribution network. The backside power distribution network may include backside supply rails for distributing power to the active device 110 and other active devices on the chip 100.

In the example shown in FIG. 1D, the top-most backside metal layer is referred to as backside metal layer BM0. The backside metal layer immediately below backside metal layer BM0 is referred to as backside metal layer BM1, and so forth. Although two backside metal layers (i.e., BM0 and BM1) are shown in FIG. 1D for ease of illustration, it is to be appreciated that the backside layers 155 may include additional metal layers below backside metal layer BM1.

In the example shown in FIG. 1D, the chip 100 includes a backside contact 160 formed on a bottom surface (i.e., backside surface) of the first source/drain 112. The backside contact 160 may be formed (i.e., patterned) from a backside contact layer BSC using, for example, lithographic and etching processes.

The chip 100 may also include a backside via 165 disposed between the backside contact 160 and backside metal layer BM0 for coupling the first source/drain 112 to backside metal layer BM0. The backside layers 155 also include vias that provide coupling between the backside metal layers including a via BV0 that provides coupling between backside metal layer BM0 and backside metal layer BM1. The chip 100 may also include a through via 170 that provides coupling between the frontside metal layer M0 and the backside metal layer BM0.

In certain aspects, the frontside layers 105 are patterned to provide signal routing for the active devices (e.g., the active device 110) on the chip 100 and the backside layers 155 are patterned to form a backside power distribution network (BSPDN) to provide power to the active devices from the backside. Moving the power distribution to the backside layers 155 helps reduce routing congestion compared with the case where the frontside layers 105 are used for both signal routing and power distribution. The reduced routing congestion allows the metal paths (also referred to as metal wires) of the BSPDN to be made wider and/or thicker, which reduces resistances (and hence IR drops) in the BSPDN. In this regard, FIG. 1D shows an example in which the backside metal layer BM0 is thicker than the frontside metal layer M0.

Capacitors may be integrated on the chip 100 for various applications. For example, integrated capacitors may be used to build a capacitor array in an analog-to-digital converter (ADC) and/or a digital-to-analog converter (DAC). The capacitor array may include multiple capacitors in which the capacitance of each of capacitors is a respective multiple of a unit capacitance. In some implementations, the capacitors in the capacitor array may be binary-weighted in which the capacitance of each of the capacitors is a respective power of two of the unit capacitance. For example, the capacitor array may include a first capacitor with a capacitance of C, a second capacitor with a capacitance of 2C, a third capacitor with a capacitance of 4C, a fourth capacitor with a capacitance of 8C, and so forth. In this example, the unit capacitance is C.

A challenge with integrating capacitors on the chip 100 is that process variations can lead to variations in the capacitances and the resistances of the capacitors. This may make it difficult to achieve precise capacitance ratios between capacitors in a capacitor array, which degrades the performance an ADC and/or a DAC including the capacitor array.

In the frontside layers 105, a lower metal layer (e.g., metal layer M0) may have a finer metal pitch and thinner metal thickness than an upper metal layer (e.g., metal layer M7), as shown in FIG. 1A. Because of the finer metal pitch and the thinner metal thickness of the lower metal layer, the capacitances of capacitors formed in the lower metal layer are more sensitive to process variation than the capacitances of capacitors formed in the upper metal layer. In addition, multiple patterning may be used to pattern the lower metal layer to achieve the fine metal pitch, which can further increase capacitance variation. For these reasons, capacitors may be formed in the upper metal layer (e.g., metal layer M7) to reduce capacitance sensitivity to process variation.

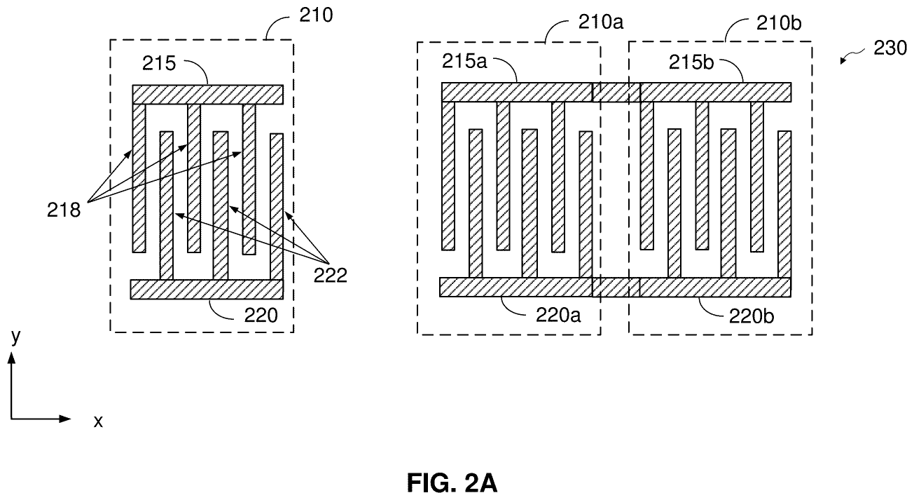

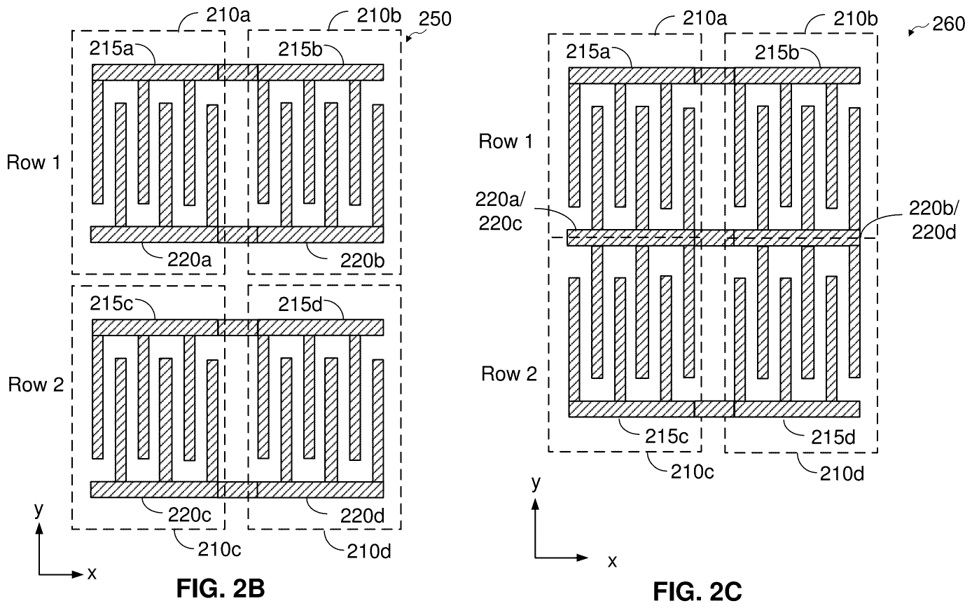

FIG. 2A shows a top view of an exemplary unit capacitor 210 (also referred to as a unit capacitor cell) according to certain aspects. The unit capacitor 210 may be formed in one or more upper metal layers (e.g., metal layer M7) by patterning the one or more upper metal layers (e.g., using lithographic and etching processes) to form the unit capacitor 210.

In the example in FIG. 2A, the unit capacitor 210 is implemented with a multiple finger capacitor (also referred to as an interdigitated capacitor) including a first terminal 215, a second terminal 220, first fingers 218, and second fingers 222. In this example, each of the first terminal 215 and the second terminal 220 extends in a first direction (e.g., x direction), and the first terminal 215 and the second terminal 220 are spaced apart in a second direction (e.g., y direction) perpendicular (i.e., orthogonal) to the first direction.

The first fingers 218 are coupled to the first terminal 215 and extend in the second direction (e.g., y direction). The second fingers 222 are coupled to the second terminal 220 and extend in the second direction (e.g., y direction). The first fingers 218 and the second fingers 222 are interlaced (i.e., interdigitated), and the gaps between the first fingers 218 and the second fingers 222 are filled with a dielectric. The terminals 215 and 220 may be located in the same metal layer as the fingers 218 and 222.

In this example, a unit capacitance of C may be defined as the capacitance of the unit capacitor 210. A capacitor having a capacitance equal to a multiple of the unit capacitance may be formed by coupling multiple instances (i.e., copies) of the unit capacitor 210 in parallel. In this regard, FIG. 2A shows an example of a capacitor 230 having a capacitance equal to 2C. In this example, the capacitor 230 includes a first unit capacitor 210a and a second unit capacitor 210b coupled in parallel where each of the unit capacitors 210a and 210b is a separate instance of the unit capacitor 210. As shown in FIG. 2A, the first terminal 215a of the first unit capacitor 210a is coupled to the first terminal 215b of the second unit capacitor 210b, and the second terminal 220a of the first unit capacitor 210a is coupled to the second terminal 220b of the second unit capacitor 210b.

A capacitor with a capacitance equal to 4C may be formed by coupling four instances of the unit capacitor 210 in parallel, a capacitor with a capacitance equal to 8C may be formed by coupling eight instances of the unit capacitor 210 in parallel, and so forth. Thus, the unit capacitor 210 shown in FIG. 2A may be duplicated many times on the chip 100 to form binary-weighted capacitors in a capacitor array. However, it is to be appreciated that the unit capacitor 210 is not limited to this example.

In certain aspects, multiple instances of the unit capacitor 210 may be formed in multiple metal layers in the frontside layers 105. For example, the fingers of first instances of the unit capacitor 210 may be formed in metal layer M7 and the fingers of second instances of the unit capacitor 210 may be formed in metal layer M8 (which neighbors metal layer M7). In this example, the fingers in metal layer M8 may be rotated 90 degrees with respect to the fingers in metal layer M7 such that the fingers in metal layer M7 are orthogonal to the fingers in metal layer M8.

FIG. 2A shows an example in which multiple instances of the unit capacitor 210 are arrayed in the x direction. However, it is to be appreciated that multiple instances of the unit capacitor 210 may also be arrayed in both the x direction and the y direction to form a two-dimensional (2D) array. In this regard FIG. 2B shows an example of a 2D array 250 including multiple unit capacitors 210a to 210d arranged in two rows where each of the unit capacitors 210a to 210d is a separate instance of the unit capacitor 210. In the example in FIG. 2B, the unit capacitors 210a and 210b are in a first one of the rows (labeled “Row1”) and the unit capacitors 210c and 210d are in a second one of the rows (labeled “Row2”). In this example, the second row is a duplicate of the first row. The first terminals 215a and 215b of the unit capacitors 210a and 210b may be coupled to the first terminals 215c and 215d of the unit capacitors 210c and 210d by a metal path (not shown). Also, the second terminals 220a and 220b of the unit capacitors 210a and 210b may be coupled to the second terminals 220c and 220d of the unit capacitors 210c and 210d by a metal path (not shown).

FIG. 2C shows another example of a 2D array 260 including the unit capacitors 210a to 210d arranged in two rows. In this example, the unit capacitors 210c and 210d in the second row (labeled “Row2”) are vertically flipped with respect to the unit capacitors 210a and 210b in the first row (labeled “Row1”). This allows the second terminals 220c and 220d of the unit capacitors 210c and 210d to be merged with the second terminals 220a and 220b of the unit capacitors 210a and 210b, as shown in FIG. 2B. In this example, the first terminals 215a and 215b of the unit capacitors 210a and 210b may be coupled to the first terminals 215c and 215d of the unit capacitors 210c and 210d by a metal path (not shown).

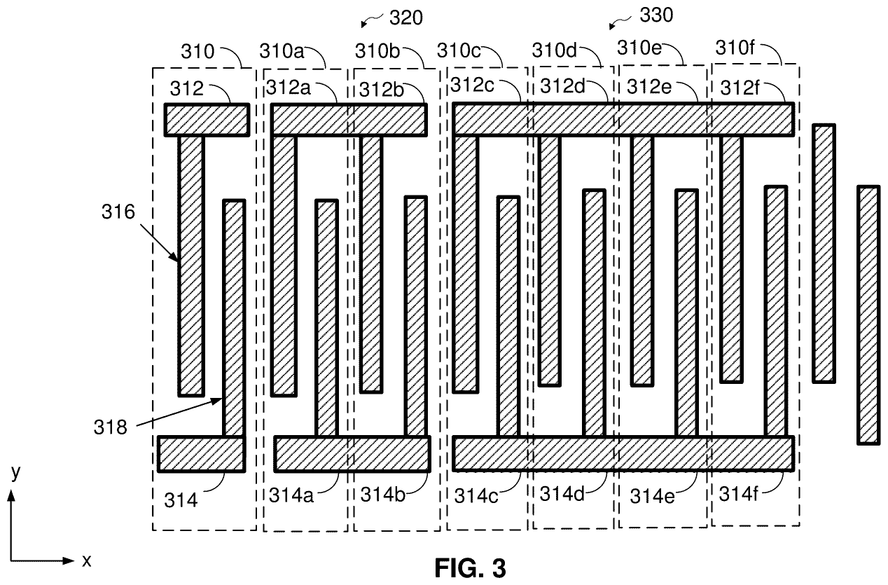

FIG. 3 shows a top view of another exemplary unit capacitor 310 (also referred to as a unit capacitor cell) according to certain aspects. The unit capacitor 310 may be formed in one or more upper metal layers (e.g., metal layer M7) by patterning the one or more upper metal layers (e.g., using lithographic and etching processes) to form the unit capacitor 310.

In the example in FIG. 3, the unit capacitor 310 includes first terminal 312, a second terminal 314, a first finger 316, and a second finger 328. In this example, each of the first terminal 312 and the second terminal 314 extends in a first direction (e.g., x direction), and the first terminal 312 and the second terminal 314 are spaced apart in a second direction (e.g., y direction) perpendicular (i.e., orthogonal) to the first direction. The first finger 316 is coupled to the first terminal 312 and extends in the second direction (e.g., y direction). The second finger 318 is coupled to the second terminal 314 and extends in the second direction (e.g., y direction). The gap between the first finger 316 and the second finger 318 is filled with a dielectric. The terminals 312 and 314 may be located in the same metal layer as the fingers 316 and 318.

In this example, a unit capacitance of C may be defined as the capacitance of the unit capacitor 310. A capacitor having a capacitance equal to a multiple of the unit capacitance may be formed by coupling multiple instances (i.e., copies) of the unit capacitor 310 in parallel. In this regard, FIG. 3 shows an example of a capacitor 320 having a capacitance equal to 2C. In this example, the capacitor 320 includes a first unit capacitor 310a and a second unit capacitor 310b coupled in parallel where each of the unit capacitors 310a and 310b is a separate instance of the unit capacitor 310. As shown in FIG. 3, the first terminal 312a of the first unit capacitor 310a is coupled to the first terminal 312b of the second unit capacitor 310b, and the second terminal 314a of the first unit capacitor 310a is coupled to the second terminal 314b of the second unit capacitor 310b.

FIG. 3 also shows an example of a capacitor 330 having a capacitance equal to 4C. In this example, the capacitor 330 includes unit capacitors 310c to 310f coupled in parallel where each of the unit capacitors 310c to 310f is a separate instance of the unit capacitor 310. As shown in FIG. 3, the first terminals 312c to 312f of the unit capacitors 310c to 310f are coupled together (e.g., to form a contiguous first terminal of the capacitor 330), and the second terminals 314c to 314f of the unit capacitors 310c to 310f are coupled together (e.g., to form a contiguous second terminal of the capacitor 330).

A capacitor with a capacitance equal to 8C may be formed by coupling eight instances of the unit capacitor 310 in parallel, a capacitor with a capacitance equal to 16C may be formed by coupling sixteen instances of the unit capacitor 310 in parallel, and so forth. Thus, the unit capacitor 310 shown in FIG. 3 may be duplicated many times on the chip 100 to form binary-weighted capacitors in a capacitor array. However, it is to be appreciated that the unit capacitor 310 is not limited to this example.

In certain aspects, the fingers of multiple instances of the unit capacitor 310 may be formed in a metal layer (e.g., metal layer M7) in a preferred direction. In this example, one or more shields for the fingers of the multiple instances of the unit capacitor 310 may be formed in neighboring metal layers (e.g., metal layers M6 and M8). The one or more shields may be used to shield the fingers from noise. Another purpose of the one or more shields may be to have a certain and fixed parasitic capacitance (since each unit is shielded in a same way to avoid variant surroundings).

It is desirable to increase the capacitance density of a unit capacitor. This is because a higher capacitance density allows the unit capacitor to occupy a smaller chip area (i.e., area in x-y directions) for a given unit capacitance, which saves chip area.

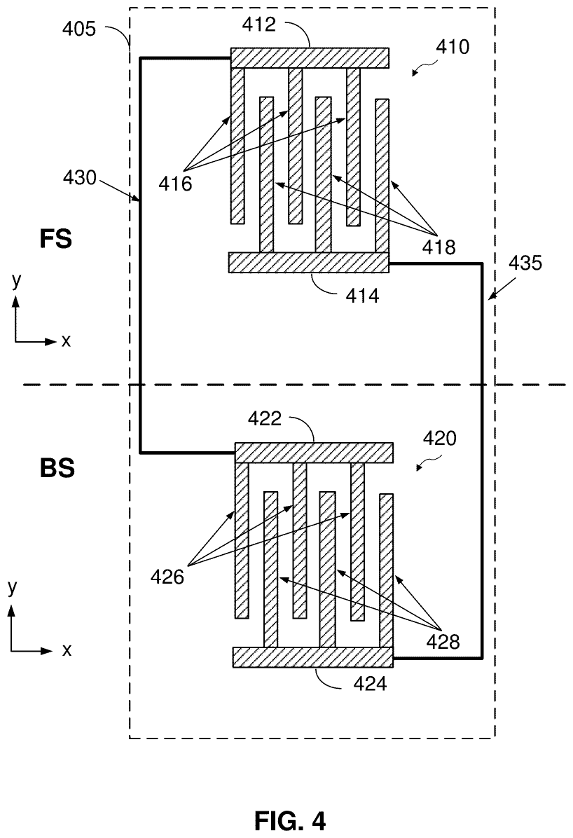

In this regard, FIG. 4 shows an example of a unit capacitor 405 including a frontside capacitor 410 and a backside capacitor 420 coupled in parallel by vertical coupling structures 430 and 435. As discussed further below, the backside capacitor 420 increases capacitance density compared with a unit capacitor having only the frontside capacitor 410. As used herein, a “frontside capacitor” is a capacitor formed in one or more layers of the frontside layers 105 (e.g., using lithographic and etching processes), and a “backside capacitor” is a capacitor formed in one or more layers of the backside layers 155 (e.g., using lithographic and etching processes). The layers in which the active devices (e.g., the active device 110) are formed are between the frontside layers 105 and the backside layers 155. In this disclosure, a capacitor (e.g., unit capacitor 405) including both a frontside capacitor and a backside capacitor may also be referred to as a “combined capacitor”.

FIG. 4 shows a top view of the frontside capacitor 410 and a top view of the backside capacitor 420. In FIG. 4, structures shown above the dashed line reside in the frontside layers 105 and structures shown below the dashed line reside in the backside layers 155. This is done to show an unobstructed top view of both the frontside capacitor 410 and the backside capacitor 420 in FIG. 4. It is to be appreciated that the frontside capacitor 410 and the backside capacitor 420 may be spaced apart in the z direction and the frontside capacitor 410 may overlap the backside capacitor 420 in the x-y directions.

In the example in FIG. 4, the frontside capacitor 410 is implemented with a multiple finger capacitor (also referred to as an interdigitated capacitor) including a first terminal 412, a second terminal 414, first fingers 416, and second fingers 418. In this example, each of the first terminal 412 and the second terminal 414 extends in a first direction (e.g., x direction), and the first terminal 412 and the second terminal 414 are spaced apart in a second direction (e.g., y direction) perpendicular (i.e., orthogonal) to the first direction.

The first fingers 416 are coupled to the first terminal 412 and extend in the second direction (e.g., y direction). The second fingers 418 are coupled to the second terminal 414 and extend in the second direction (e.g., y direction). The first fingers 416 and the second fingers 418 are interlaced (i.e., interdigitated), and the gaps between the first fingers 416 and the second fingers 418 are filled with a dielectric.

The frontside capacitor 410 may be formed in one or more upper metal layers (e.g., metal layer M7) of the frontside layers 105. As discussed above, capacitors formed in the upper metal layers are less sensitive to capacitance variation due to process variation compared with capacitors formed in the lower metal layers of the frontside layers 105. Within the disclosure, a finger formed in one or more layers of the frontside layers 105 may also be referred to as a frontside finger, and a terminal formed in one or more layers of the frontside layers 105 may also be referred to as a frontside terminal.

In the example in FIG. 4, the backside capacitor 420 is implemented with a multiple finger capacitor (also referred to as an interdigitated capacitor) including a first terminal 422, a second terminal 424, first fingers 426, and second fingers 428. In this example, each of the first terminal 422 and the second terminal 424 extends in a first direction (e.g., x direction), and the first terminal 422 and the second terminal 424 are spaced apart in a second direction (e.g., y direction) perpendicular (i.e., orthogonal) to the first direction.

The first fingers 426 are coupled to the first terminal 422 and extend in the second direction (e.g., y direction). The second fingers 428 are coupled to the second terminal 424 and extend in the second direction (e.g., y direction). The first fingers 426 and the second fingers 428 are interlaced (i.e., interdigitated), and the gaps between the first fingers 426 and the second fingers 428 are filled with a dielectric. As discussed further below, the dielectric between the fingers 426 and 428 of the backside capacitor 420 may differ from the dielectric between the fingers 416 and 418 of the frontside capacitor 410.

The backside capacitor 420 is formed in one or more metal layers (e.g., metal layer M7) of the backside layers 155. For example, the fingers 426 and 428 of the backside capacitor 420 may be formed in backside metal layer BM0 or BM1 shown in FIG. 1D (e.g., using lithographic and etching processes). Within the disclosure, a finger formed in one or more layers of the backside layers 155 may also be referred to as a backside finger, and a terminal formed in one or more layers of the backside layers 155 may also be referred to as a backside terminal.

In certain aspects, the metal pitches and thicknesses of backside metal layers BM0 and BM1 are larger than the metal pitches and thicknesses of the lower frontside metal layers M0 and M1. This is because the backside metal layers BM0 and BM1 are used for the BSPDN in which the larger thicknesses reduce IR drops in the BSPDN. In contrast, the lower frontside metal layers M0 and M1 are used for signal routing to individual active devices. In this example, the larger metal pitches and thicknesses of backside metal layers BM0 and BM1 reduce capacitance sensitivity to process variation. In certain aspects, the metal pitches and thicknesses of the metal layers BM0 and BM1 may be similar to the metal pitches and thicknesses of upper metal layers (e.g., metal layers M6 and M7) of the frontside layers 105.

In certain aspects, the dielectric in the gaps between the fingers 426 and 428 of the backside capacitor 420 has a higher dielectric constant k than the dielectric in the gaps between the fingers 416 and 418 of the frontside capacitor 410. The higher dielectric constant k enhances the capacitance density of the backside capacitor 420 for a given spacing between fingers. In this example, the dielectric constant k of dielectric layers in the frontside layers 105 may be made lower to reduce parasitic capacitances, which can degrade high-frequency signals propagating through signal routing in the frontside layers 105. The dielectric constant k of dielectric layers in the backside layers 155 may be made higher since parasitic capacitances may not be an issue with the BSPDN formed in the backside layers 155. In certain aspects, the higher dielectric constant k may enhance the capacitances of decoupling capacitors in the BSPDN used to reduce voltage droops in the BSPDN. For example, a dielectric layer in the frontside layer 105 may include a porous ultra low-k (ULK) dielectric and a dielectric layer in the backside layers 155 may include a silicon oxide. However, it is to be appreciated that the present disclosure is not limited to this example.

The vertical coupling structures 430 and 435 couple the frontside capacitor 410 and the backside capacitor 420 in parallel. In the example in FIG. 4, the vertical coupling structure 430 couples the first terminal 412 of the frontside capacitor 410 to the first terminal 422 of the backside capacitor 420, and the vertical coupling structure 435 couples the second terminal 414 of the frontside capacitor 410 to the second terminal 424 of the backside capacitor 420. In FIG. 4, each of the vertical coupling structures 430 and 435 is depicted as a line between the terminals that are coupled by the vertical coupling structure. FIG. 4 is not intended to show the physical structures of the vertical coupling structures 430 and 435.

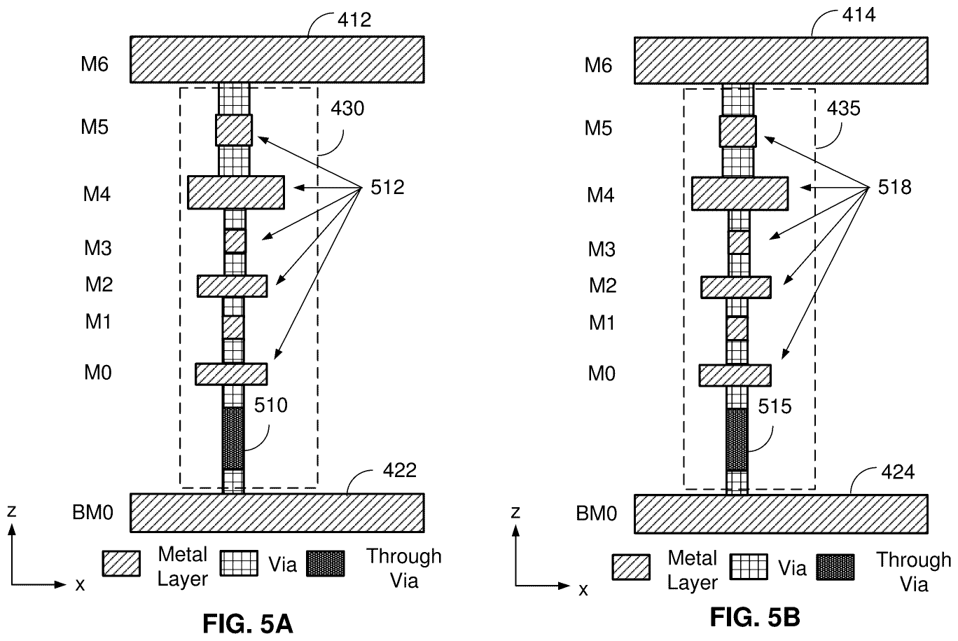

FIG. 5A shows a side view of an example implementation of the vertical coupling structure 430 coupling the first terminal 412 of the frontside capacitor 410 to the first terminal 422 of the backside capacitor 420. In this example, the first terminal 412 of the frontside capacitor 410 is above the first terminal 422 of the backside capacitor 420. Also, in this example, the first terminal 412 of the frontside capacitor 410 is formed in metal layer M6 and the first terminal 422 of the backside capacitor 420 is formed in backside metal layer BM0. However, it is to be appreciated that the present disclosure is not limited to this example, and that the first terminal 412 of the frontside capacitor 410 may be formed in a different frontside metal layer and/or the first terminal 422 of the backside capacitor 420 may be formed in a different backside metal layer.

In the example shown in FIG. 5A, the vertical coupling structure 430 extends in the z direction between the first terminal 412 of the frontside capacitor 410 and the first terminal 422 of the backside capacitor 420. The vertical coupling structure 430 includes metal interconnects 512 formed in the intermediate metal layers (e.g., metal layers M0 to M5) between the metal layer (e.g., metal layer M6) in which the first terminal 412 of the frontside capacitor 410 is formed and the backside layer (e.g., backside metal layer BM0) in which the first terminal 422 of the backside capacitor 420 is formed. The vertical coupling structure 430 also includes vias coupling the metal interconnects 512. The vias include a through via 510 for coupling the frontside metal layer M0 and the backside metal layer BM0.

FIG. 5B shows a side view of an example implementation of the vertical coupling structure 435 coupling the second terminal 414 of the frontside capacitor 410 to the second terminal 424 of the backside capacitor 420. In this example, the second terminal 414 of the frontside capacitor 410 is above the second terminal 424 of the backside capacitor 420.

In the example shown in FIG. 5B, the vertical coupling structure 430 extends in the z direction between the second terminal 414 of the frontside capacitor 410 and the second terminal 424 of the backside capacitor 420. The vertical coupling structure 435 includes metal interconnects 518 formed in the intermediate metal layers (e.g., metal layers M0 to M5) between the metal layer (e.g., metal layer M6) in which the second terminal 414 of the frontside capacitor 410 is formed and the backside layer (e.g., backside metal layer BM0) in which the second terminal 424 of the backside capacitor 420 is formed. The vertical coupling structure 435 also includes vias coupling the metal interconnects 518. The vias include a through via 515 for coupling the frontside metal layer M0 and the backside metal layer BM0.

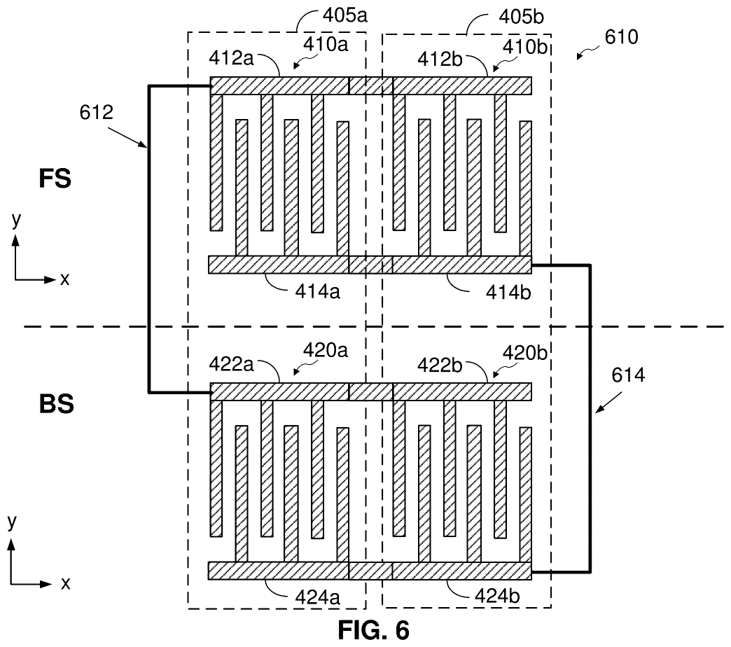

In this example, a unit capacitance of C may be defined as the capacitance of the unit capacitor 405. A capacitor having a capacitance equal to a multiple of the unit capacitance may be formed by coupling multiple instances (i.e., copies) of the unit capacitor 405 in parallel. In this regard, FIG. 6 shows an example of a capacitor 610 having a capacitance equal to 2C. In this example, the capacitor 230 includes a first unit capacitor 405a and a second unit capacitor 405b coupled in parallel where each of the unit capacitors 405a and 405b is a separate instance of the unit capacitor 405. As shown in FIG. 6, the first terminals 412a and 412b of the frontside capacitors 410a and 410b are coupled together, and the second terminals 414a and 414b of the frontside capacitors 410a and 410b are coupled together. Also, the first terminals 422a and 422b of the backside capacitors 420a and 420b are coupled together, and the second terminals 424a and 424b of the backside capacitors 420a and 420b are coupled together.

In this example, the first terminals 412a and 412b of the frontside capacitors 410a and 410b are coupled to the first terminals 422a and 422b of the backside capacitors 420a and 420b by vertical coupling structure 612, which may include one or more instances of the vertical coupling structure 430. The second terminals 414a and 414b of the frontside capacitors 410a and 410b are coupled to the second terminals 424a and 424b of the backside capacitors 420a and 420b by vertical coupling structure 614, which may include one or more instances of the vertical coupling structure 435.

A capacitor with a capacitance equal to 4C may be formed by coupling four instances of the unit capacitor 405 in parallel, a capacitor with a capacitance equal to 8C may be formed by coupling eight instances of the unit capacitor 405 in parallel, and so forth. Thus, the unit capacitor 405 shown in FIG. 4 may be duplicated many times on the chip 100 to form binary-weighted capacitors in a capacitor array. However, it is to be appreciated that the unit capacitor 405 is not limited to this example.

It is to be appreciated that multiple instances of the unit capacitor 405 may be arrayed in the x direction or arrayed in both the x direction and the y direction to form a 2D array (e.g., in the manner shown in FIG. 2B or FIG. 2C).

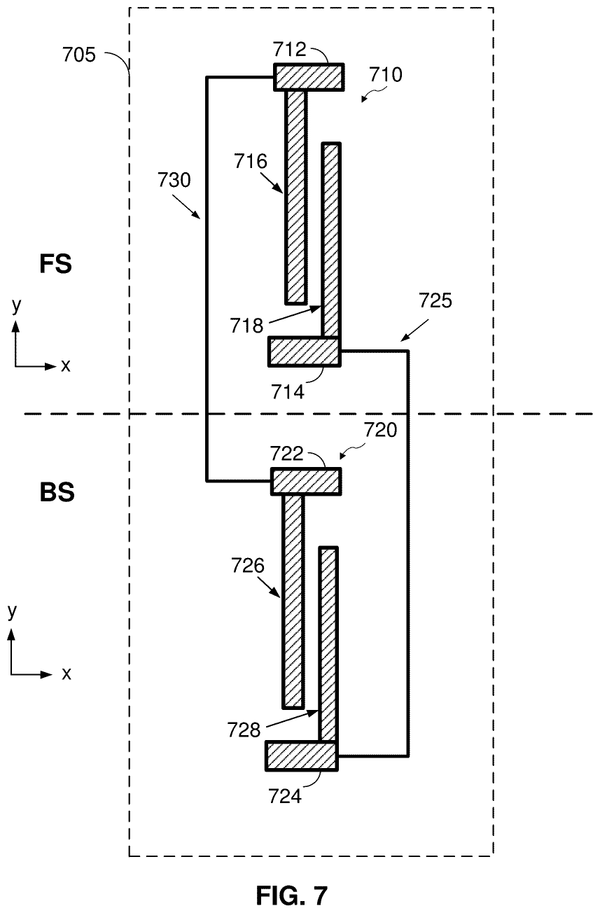

FIG. 7 shows another example of a unit capacitor 705 including a frontside capacitor 710 and a backside capacitor 720 coupled in parallel by vertical coupling structures 730 and 735. FIG. 7 shows a top view of the frontside capacitor 710 and a top view of the backside capacitor 720. In FIG. 7, structures shown above the dashed line reside in the frontside layers 105 and structures shown below the dashed line reside in the backside layers 155. This is done to show an unobstructed top view of both the frontside capacitor 710 and the backside capacitor 720 in FIG. 7. It is to be appreciated that the frontside capacitor 710 may be located above and overlap the backside capacitor 720 in the x-y directions. The frontside capacitor 710 may be formed in one or more upper metal layers (e.g., metal layer M7) of the frontside layers 105.

In the example in FIG. 7, the frontside capacitor 710 includes a first terminal 712, a second terminal 714, a first finger 716, and second finger 718. In this example, each of the first terminal 712 and the second terminal 714 extends in a first direction (e.g., x direction), and the first terminal 712 and the second terminal 714 are spaced apart in a second direction (e.g., y direction) perpendicular (i.e., orthogonal) to the first direction. The first finger 716 is coupled to the first terminal 712 and extends in the second direction (e.g., y direction). The second finger 718 is coupled to the second terminal 714 and extends in the second direction (e.g., y direction). The gap between the first finger 716 and the second finger 718 of the frontside capacitor 710 is filled with a dielectric.

In the example in FIG. 7, the backside capacitor 720 includes a first terminal 722, a second terminal 724, a first finger 726, and second finger 728. In this example, each of the first terminal 722 and the second terminal 724 extends in a first direction (e.g., x direction), and the first terminal 722 and the second terminal 724 are spaced apart in a second direction (e.g., y direction) perpendicular (i.e., orthogonal) to the first direction. The first finger 726 is coupled to the first terminal 722 and extends in the second direction (e.g., y direction). The second finger 728 is coupled to the second terminal 724 and extends in the second direction (e.g., y direction). The gap between the first finger 726 and the second finger 728 of the backside capacitor 720 is filled with a dielectric, which may have a higher dielectric constant k than the dielectric between the first finger 716 and the second finger 718 of the frontside capacitor 710.

The vertical coupling structures 730 and 735 couple the frontside capacitor 710 and the backside capacitor 720 in parallel. In the example in FIG. 7, the vertical coupling structure 730 couples the first terminal 712 of the frontside capacitor 710 to the first terminal 714 of the backside capacitor 720, and the vertical coupling structure 735 couples the second terminal 714 of the frontside capacitor 710 to the second terminal 724 of the backside capacitor 720. In FIG. 7, each of the vertical coupling structures 730 and 735 is depicted as a line between the terminals that are coupled by the vertical coupling structure. FIG. 7 is not intended to show the physical structures of the vertical coupling structures.

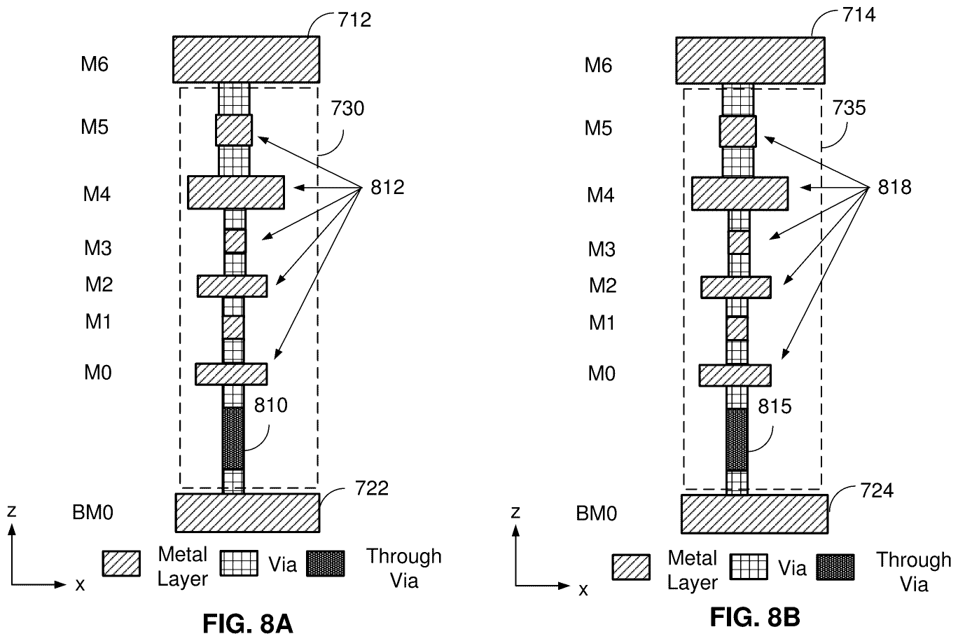

FIG. 8A shows a side view of an example implementation of the vertical coupling structure 730 coupling the first terminal 712 of the frontside capacitor 710 to the first terminal 714 of the backside capacitor 720. In this example, the first terminal 712 of the frontside capacitor 710 is above the first terminal 722 of the backside capacitor 720.

In the example shown in FIG. 8A, the vertical coupling structure 730 extends in the z direction between the first terminal 712 of the frontside capacitor 710 and the first terminal 722 of the backside capacitor 720. The vertical coupling structure 730 includes metal interconnects 812 formed in the intermediate metal layers between the metal layer in which the first terminal 712 of the frontside capacitor 710 is formed and the backside layer in which the first terminal 722 of the backside capacitor 720 is formed. The vertical coupling structure 730 also includes vias coupling the metal interconnects 812. The vias include a through via 810 for coupling the frontside metal layer M0 and the backside metal layer BM0.

FIG. 8B shows a side view of an example implementation of the vertical coupling structure 735 coupling the second terminal 714 of the frontside capacitor 710 to the second terminal 724 of the backside capacitor 720. In this example, the second terminal 714 of the frontside capacitor 710 is above the second terminal 724 of the backside capacitor 720.

In the example shown in FIG. 8B, the vertical coupling structure 735 extends in the z direction between the second terminal 714 of the frontside capacitor 710 and the second terminal 724 of the backside capacitor 720. The vertical coupling structure 735 includes metal interconnects 818 formed in the intermediate metal layers between the metal layer in which the second terminal 714 of the frontside capacitor 710 is formed and the backside layer in which the second terminal 724 of the backside capacitor 720 is formed. The vertical coupling structure 735 also includes vias coupling the metal interconnects 818. The vias include a through via 815 for coupling the frontside metal layer M0 and the backside metal layer BM0.

In this example, a unit capacitance of C may be defined as the capacitance of the unit capacitor 705. A capacitor having a capacitance equal to a multiple of the unit capacitance may be formed by coupling multiple instances (i.e., copies) of the unit capacitor 405 in parallel.

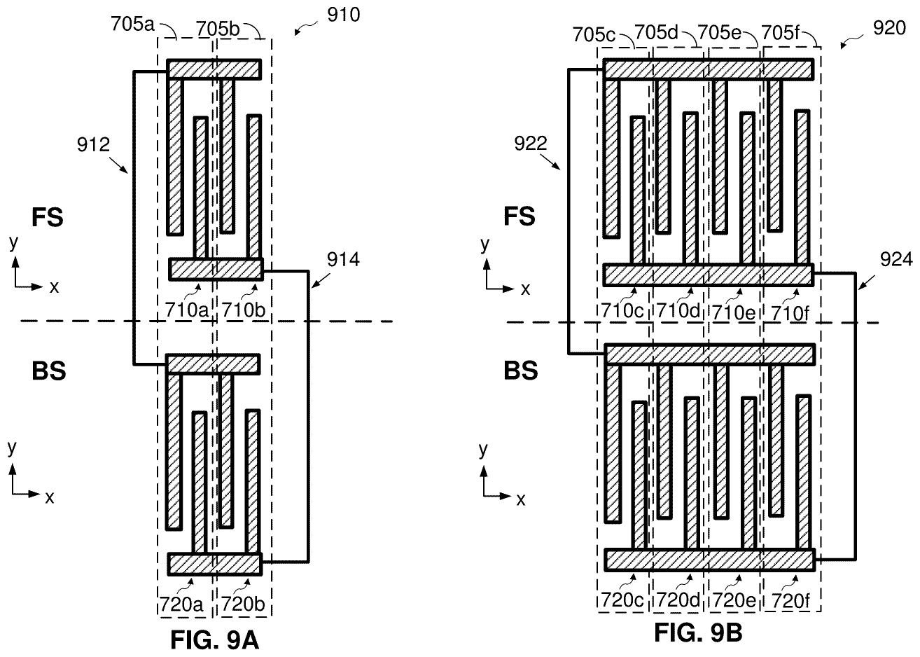

In this regard, FIG. 9A shows an example of a capacitor 910 having a capacitance equal to 2C. In this example, the capacitor 910 includes a first unit capacitor 705a and a second unit capacitor 705b coupled in parallel where each of the unit capacitors 705a and 705b is a separate instance of the unit capacitor 705. The frontside capacitors 710a and 710b and the backside capacitors 720a and 720b of the unit capacitors 705a and 705b are coupled in parallel by vertical coupling structures 912 and 914. The vertical coupling structure 912 may include one or more instances of the vertical coupling structure 730 and the vertical coupling structure 914 may include one or more instances of the vertical coupling structure 735.

FIG. 9B shows an example of a capacitor 920 having a capacitance equal to 4C. In this example, the capacitor 920 includes unit capacitors 705c to 705f coupled in parallel where each of the unit capacitors 705c to 705f is a separate instance of the unit capacitor 705. The frontside capacitors 710c to 710f and the backside capacitors 720c to 720f of the unit capacitors 705c to 705f are coupled in parallel by vertical coupling structures 922 and 924. The vertical coupling structure 922 may include one or more instances of the vertical coupling structure 730 and the vertical coupling structure 924 may include one or more instances of the vertical coupling structure 735.

A capacitor with a capacitance equal to 8C may be formed by coupling eight instances of the unit capacitor 705 in parallel, a capacitor with a capacitance equal to 16C may be formed by coupling sixteen instances of the unit capacitor 705 in parallel, and so forth. Thus, the unit capacitor 705 shown in FIG. 7 may be duplicated many times on the chip 100 to form binary-weighted capacitors in a capacitor array. However, it is to be appreciated that the unit capacitor 705 is not limited to this example.

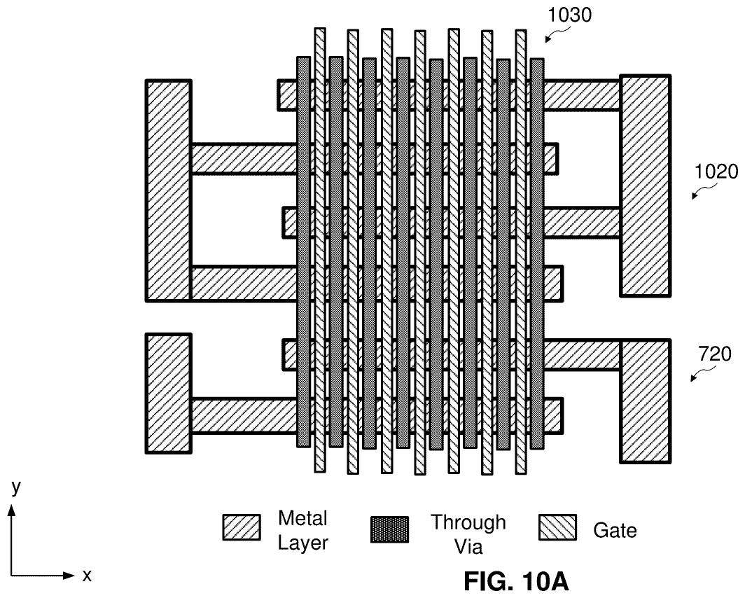

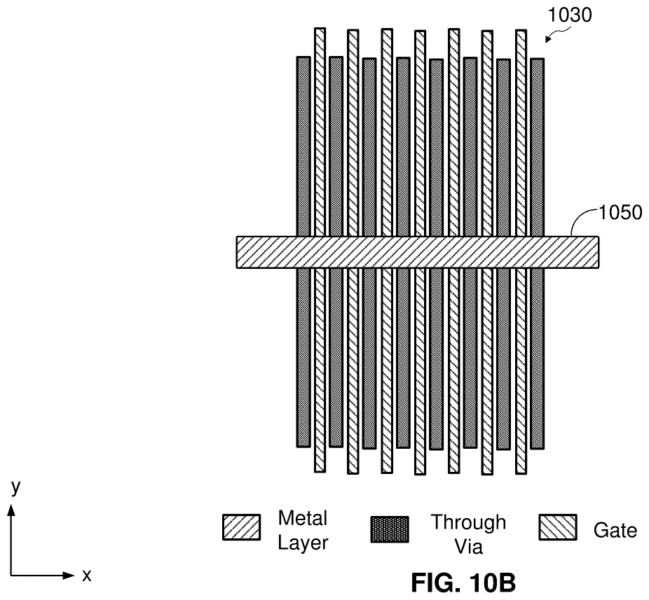

In certain aspects, a top shield for one or more backside capacitors may be formed using gates and through vias according to certain aspects. In this regard, FIG. 10A shows an example of the backside capacitor 720 in which the backside capacitor 720 is rotated 90 degrees with respect to the exemplary orientation of the backside capacitor 720 shown in FIG. 7. In this example, the backside capacitor 720 may or may not be coupled to the frontside capacitor 710 (i.e., the backside capacitor 720 may or may not be part of the unit capacitor 705). FIG. 10A also shows an example of a backside capacitor 1020 which includes two instances of the backside capacitor 720 coupled in parallel. The backside capacitor 1020 may or may not be part of the capacitor 910 shown in FIG. 9. The fingers of the backside capacitors 720 and 1020 are formed in a backside metal layer (e.g., backside metal layer BM0 or BM1).

In this example, the chip 100 includes a top shield 1030 overlapping the fingers of the backside capacitors 720 and 1020 in the x-y directions. The top shield 1030 includes gates and long through vias extending in the y direction over the fingers of the backside capacitors 720 and 1020 to provide shielding for the backside capacitors 720 and 1020. In the example shown in FIG. 10A, the top shield 1030 alternates between the through vias and the gates in the x direction. Also, in this example, the fingers of the backside capacitors 720 and 1020 and the gates and the through vias of the top shield 1030 extend in orthogonal directions (e.g., the fingers extend in direction x and the gates and the through vias extend in the y direction). Using the gates and the through vias for the top shield 1030 allow the top shield 1030 to be formed using existing processes for forming gates and through vias on the chip 100.

In certain aspects, the gates and the through vias of the top shield 1030 are coupled together. In this regard, FIG. 10B shows an example in which the gates and the through vias of the top shield 1030 are coupled through a metal path 1050 formed in frontside metal layer M0. Note that the backside capacitors 720 and 1020 are not shown in FIG. 10B. In this example, each through via of the top shield 1330 is coupled to the metal path 1050 by a respective via (e.g., VD in FIG. 1D) disposed between the through via and the metal path 1050. Also, each gate of the top shield 1030 is coupled to the metal path 1050 by a respective gate via (not shown in FIG. 10B) disposed between the gate and the metal path 1050. Although one metal path 1050 is shown in the example in FIG. 10B, it is to be appreciated that the gates and the through vias of the top shield 1030 may be coupled together through two or more metal paths in frontside metal layer M0. Thus, in general, the gates and the through vias of the top shield 1030 are coupled together through one or more metal paths in metal layer M0.

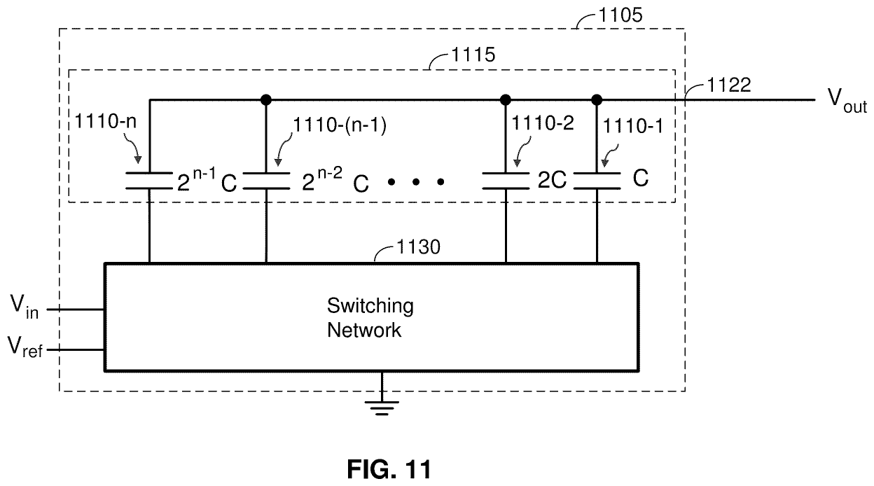

As discussed above, the unit capacitors 405 and 705 may be used to build a capacitor array on the chip 100. In this regard, FIG. 11 shows an example of a capacitor array 1115 including capacitors 1110-1 to 1110-n. The capacitance of the capacitors 1110-1 to 1110-n may be binary-weighted as shown in the example in FIG. 11. In this example, the capacitor 1110-1 has a capacitance of C, the capacitor 1110-2 has a capacitance of 2C, and so forth. The largest capacitor 1110-n in the capacitor array 1115 has a capacitance of 2ⁿ⁻¹ times C where C is a unit capacitance.

In this example, the capacitor 1110-1 may be implemented with the unit capacitor 405 or 705, the capacitor 1110-2 may be implemented with two instances of the unit capacitor 405 or 705 coupled in parallel, and so on. The largest capacitor 1110-n may be implemented with 2ⁿ⁻¹ instances of the unit capacitor 405 or 705 coupled in parallel.

In certain aspects, the capacitor array 1115 may be included in a DAC 1105, which may be used in a successive approximation register (SAR) ADC. In this example, the DAC 1105 includes the capacitor array 1115 and a switching network 1130. The first terminals of the capacitors 1110-1 to 1110-n may be coupled to the output 1122 of the DAC 1105 and the second terminals of the capacitors 1110-1 to 1110-n may be coupled to the switching network 1130, or vice versa.

In operation, the switching network 1130 is configured to selectively couple each of the capacitors 1110-1 to 1110-n to one of multiple voltages coupled to the switching network 1130. In the example shown in FIG. 11, the voltages include a reference voltage V_{ref}, an input voltage Vᵢₙ, and ground potential. However, it is to be appreciated that the present disclosure is not limited to this example.

In this example, the switching network 1130 may sample the input voltage Vᵢₙ by coupling the input voltage Vᵢₙ to the capacitors 1110-1 to 1110-n with the output 1122 grounded. After the input voltage Vᵢₙ is sampled, the switching network 1130 decouples the input voltage Vᵢₙ from the capacitors 1110-1 to 1110-n with the output 1122 decoupled from ground.

The switching network 1130 may then generate an output voltage Vₒᵤₜ at the output 1122 equal to a difference between the sampled input voltage and an analog voltage. The switching network 1130 generates the analog voltage based on a digital signal by selectively coupling each of the capacitors 1110-1 to 1110-m to the reference voltage V_{ref} or ground based on the bit values of the digital signal. The analog voltage may be between ground and the reference voltage V_{ref}. The various switching configurations for generating the analog voltage based on the digital signal are known in the art.

It is to be appreciated that aspects of the present disclosure are not limited to the exemplary DAC 1105 shown in FIG. 11, and the aspects of the present disclosure may be used in other DAC designs, ADC designs, and/or other applications.

Implementation examples are described in the following numbered clauses:

1. A chip, comprising:
a combined capacitor, comprising:
   a frontside capacitor;
   a backside capacitor; and
   vertical coupling structures coupling the frontside capacitor and the backside capacitor in parallel.

2. The chip of clause 1, wherein the frontside capacitor comprises:
a first frontside terminal extending in a first direction;
first frontside fingers coupled to the first frontside terminal and extending in a second direction orthogonal to the first direction;
a second frontside terminal extending in the first direction; and
second frontside fingers coupled to the second frontside terminal and extending in the second direction, wherein the first frontside fingers and the second frontside fingers are interlaced.

3. The chip of clause 2, wherein the backside capacitor comprises:
a first backside terminal extending in the first direction;
first backside fingers coupled to the first backside terminal and extending in the second direction;
a second backside terminal extending in the first direction; and
second backside fingers coupled to the second backside terminal and extending in the second direction, wherein the first backside fingers and the second backside fingers are interlaced.

4. The chip of clause 3, wherein the vertical coupling structures include:
a first vertical coupling structure coupling the first frontside terminal and the first backside terminal; and
a second vertical coupling structure coupling the second frontside terminal and the second backside terminal.

5. The chip of clause 3 or 4, further comprising:
a first dielectric between the first frontside fingers and the second frontside fingers: and
a second dielectric between the first backside fingers and the second backside fingers, wherein the second dielectric has a higher dielectric constant than the first dielectric.

6. The chip of any one of clauses 1 to 5, wherein:
the frontside capacitor is formed in one or more frontside metal layers of the chip;
the backside capacitor is formed in one or more backside metal layers of the chip; and
the chip includes one or more active devices between the one or more frontside metal layers and the one or more backside metal layers.

7. The chip of clause 6, wherein the one or more active devices comprises:
a first source/drain;
a second source/drain;
a gate; and
one or more channels coupled between the first source/drain and the second source/drain, wherein the one or more channels pass through the gate.

8. A chip, comprising:
a backside capacitor, comprising:
   a first terminal extending in a first direction;
      first fingers coupled to the first terminal and extending in a second direction orthogonal to the first direction;
      a second terminal extending in the first direction;
   second fingers coupled to the second terminal and extending in the second direction, wherein the first fingers and the second fingers are interlaced; and
a shield comprising gates extending over the first fingers and the second fingers in the first direction.

9. The chip of clause 8, wherein the shield further comprises vias extending over the first fingers and the second fingers in the first direction.

10. The chip of clause 9, wherein the shield alternates between the gates and the vias in the second direction.

11. The chip of clause 9 or 10, wherein each of the vias is disposed between a respective pair of the gates.

12. The chip of any one of clauses 9 to 11, wherein each of the gates is disposed between a respective pair of the vias.

13. The chip of any one of clauses 9 to 12, wherein the gates and the vias are coupled together.

14. The chip of clause 13, further comprising one or more metal paths extending over the shield, wherein the gates and the vias are coupled together through the one or more metal paths.

15. The chip of any one of clauses 8 to 14, further comprising a frontside capacitor coupled in parallel with the backside capacitor.

16. A chip, comprising:
unit capacitors coupled in parallel, wherein each of the unit capacitors comprises:
   a respective frontside capacitor;
   a respective backside capacitor; and
      respective vertical coupling structures coupling the respective frontside capacitor and the respective backside capacitor in parallel.

17. The chip of clause 16, wherein the respective frontside capacitor of each of the unit capacitors comprises:
a respective first frontside terminal extending in a first direction;
respective first frontside fingers coupled to the respective first frontside terminal and extending in a second direction orthogonal to the first direction;
a respective second frontside terminal extending in the first direction; and
respective second frontside fingers coupled to the respective second frontside terminal and extending in the second direction, wherein the respective first frontside fingers and the respective second frontside fingers are interlaced.

18. The chip of clause 17, wherein the respective backside capacitor of each of the unit capacitors comprises:
a respective first backside terminal extending in the first direction;
respective first backside fingers coupled to the respective first backside terminal and extending in the second direction;
a respective second backside terminal extending in the first direction; and
respective second backside fingers coupled to the respective second backside terminal and extending in the second direction, wherein the respective first backside fingers and the respective second backside fingers are interlaced.

19. The chip of any one of clauses 16 to 18, further comprising a switching network coupled to the unit capacitors.

20. The chip of any one of clauses 16 to 19, wherein the unit capacitors are arranged in a two-dimensional array.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a combined capacitor, comprising:
a frontside capacitor;
a backside capacitor; and
vertical coupling structures coupling the frontside capacitor and the backside capacitor in parallel.

2. The chip of claim 1, wherein the frontside capacitor comprises:
a first frontside terminal extending in a first direction;
first frontside fingers coupled to the first frontside terminal and extending in a second direction orthogonal to the first direction;
a second frontside terminal extending in the first direction; and
second frontside fingers coupled to the second frontside terminal and extending in the second direction, wherein the first frontside fingers and the second frontside fingers are interlaced.

3. The chip of claim 2, wherein the backside capacitor comprises:
a first backside terminal extending in the first direction;
first backside fingers coupled to the first backside terminal and extending in the second direction;
a second backside terminal extending in the first direction; and
second backside fingers coupled to the second backside terminal and extending in the second direction, wherein the first backside fingers and the second backside fingers are interlaced.

4. The chip of claim 3, wherein the vertical coupling structures include:
a first vertical coupling structure coupling the first frontside terminal and the first backside terminal; and
a second vertical coupling structure coupling the second frontside terminal and the second backside terminal.

5. The chip of claim 3, further comprising:
a first dielectric between the first frontside fingers and the second frontside fingers: and
a second dielectric between the first backside fingers and the second backside fingers, wherein the second dielectric has a higher dielectric constant than the first dielectric.

6. The chip of claim 1, wherein:
the frontside capacitor is formed in one or more frontside metal layers of the chip;
the backside capacitor is formed in one or more backside metal layers of the chip; and
the chip includes one or more active devices between the one or more frontside metal layers and the one or more backside metal layers.

7. The chip of claim 6, wherein the one or more active devices comprises:
a first source/drain;
a second source/drain;
a gate; and
one or more channels coupled between the first source/drain and the second source/drain, wherein the one or more channels pass through the gate.

8. A chip, comprising:
a backside capacitor, comprising:
a first terminal extending in a first direction;
first fingers coupled to the first terminal and extending in a second direction orthogonal to the first direction;
a second terminal extending in the first direction;
second fingers coupled to the second terminal and extending in the second direction, wherein the first fingers and the second fingers are interlaced; and
a shield comprising gates extending over the first fingers and the second fingers in the first direction.

9. The chip of claim 8, wherein the shield further comprises vias extending over the first fingers and the second fingers in the first direction.

10. The chip of claim 9, wherein the shield alternates between the gates and the vias in the second direction.

11. The chip of claim 9, wherein each of the vias is disposed between a respective pair of the gates.

12. The chip of claim 9, wherein each of the gates is disposed between a respective pair of the vias.

13. The chip of claim 9, wherein the gates and the vias are coupled together.

14. The chip of claim 13, further comprising one or more metal paths extending over the shield, wherein the gates and the vias are coupled together through the one or more metal paths.

15. The chip of claim 8, further comprising a frontside capacitor coupled in parallel with the backside capacitor.

16. A chip, comprising:
unit capacitors coupled in parallel, wherein each of the unit capacitors comprises:
a respective frontside capacitor;
a respective backside capacitor; and
respective vertical coupling structures coupling the respective frontside capacitor and the respective backside capacitor in parallel.

17. The chip of claim 16, wherein the respective frontside capacitor of each of the unit capacitors comprises:
a respective first frontside terminal extending in a first direction;
respective first frontside fingers coupled to the respective first frontside terminal and extending in a second direction orthogonal to the first direction;
a respective second frontside terminal extending in the first direction; and
respective second frontside fingers coupled to the respective second frontside terminal and extending in the second direction, wherein the respective first frontside fingers and the respective second frontside fingers are interlaced.

18. The chip of claim 17, wherein the respective backside capacitor of each of the unit capacitors comprises:
a respective first backside terminal extending in the first direction;
respective first backside fingers coupled to the respective first backside terminal and extending in the second direction;
a respective second backside terminal extending in the first direction; and
respective second backside fingers coupled to the respective second backside terminal and extending in the second direction, wherein the respective first backside fingers and the respective second backside fingers are interlaced.

19. The chip of claim 16, further comprising a switching network coupled to the unit capacitors.

20. The chip of claim 16, wherein the unit capacitors are arranged in a two-dimensional array.
